(19) United States
(12) Patent Application Publication
(10) Pub. No.: US 2021/0384378 A1
(43) Pub. Date: Dec. 9, 2021

(54) SEMICONDUCTOR LIGHT EMITTING DEVICE

(71) Applicant: STANLEY ELECTRIC CO., LTD., Tokyo (JP)

(72) Inventor: Kenji IKEDA, Tokyo (JP)

(73) Assignee: STANLEY ELECTRIC CO., LTD., Tokyo (JP)

(21) Appl. No.: 17/337,605

(22) Filed: Jun. 3, 2021

(30) Foreign Application Priority Data
Jun. 8, 2020 (JP) 2020-099622

(51) Int. Cl. H01L 33/38; H01L 33/32; H01L 33/20

(52) U.S. Cl. CPC H01L 33/382; H01L 33/20; H01L 33/32

(57) ABSTRACT

A semiconductor light emitting device includes a semiconductor light emitting element, a substrate mounted with the light emitting element and including a substrate joining surface having an inner substrate joining surface to which an annular-shaped substrate metal layer is fixed, and an outer substrate joining surface being an outer adjacent region of the inner substrate joining surface, and a light transmitting cap which has a window part transmitting light and a flange having a flange joining surface to which are annular-shaped flange metal layer is fixed, and which is sealed and joined to the substrate. A sealing joining section between the substrate and the cap has an inner joining part at which the substrate metal layer and the flange metal layer are joined by a metal joining material, and an outer joining part being an outer adjacent region of the inner joining part and being joined by an inorganic adhesive.

### BACKGROUND OF THE INVENTION

### 1. Field of the Invention

The present invention relates to a semiconductor light emitting device, and particularly to a semiconductor light emitting device having a semiconductor light emitting element enclosed thereinside which emits ultraviolet light.

### 2. Description of the Related Art

There has heretofore been known a semiconductor device having a semiconductor element enclosed inside a semiconductor package. In the case of a semiconductor light emitting module, a transparent window member such as glass which transmits light from a semiconductor light emitting element is joined to a support body mounted with the semiconductor light emitting element and airtightly sealed to each other.

There has been disclosed in, for example, in Patent Literatures 1 (Japanese Patent Application Laid-Open No. 2015-18873) and 2 (Japanese Patent Application Laid-Open No. 2018-93137), a semiconductor light emitting module in which a substrate provided with a recess part accommodating a semiconductor light emitting element therein, and a window member are joined.

Further, there has been disclosed in Patent Literatures 3 (Japanese Patent Application Laid-Open No. 2016-127255) and 4 (Japanese Patent Application Laid-Open No. 2016-127249), an ultraviolet light emitting device in which a mounting substrate mounted with an ultraviolet light emitting element, a spacer, and a cover formed of glass are joined.

### SUMMARY OF THE INVENTION

However, a further improvement in scalability between the substrate and the window member and joining reliability has been requested. A semiconductor light emitting element which radiates ultraviolet light, particularly an AlGaN-based semiconductor light emitting element is easy to deteriorate when being inadequate in airtightness. A semiconductor device mounted with the semiconductor light emitting element is required to have high airtightness.

Further, an AlGaN-based crystal is degraded by moisture. In particular, the shorter the light emitting wavelength, the more Al composition increases and the more easily it deteriorates. Thus, a structure in which a substrate and a glass cover are kept airtight by a metal joining material has been adopted as an airtight structure which prevents moisture from entering into a package accommodating a light emitting element therein, but a problem arises in that the structure is insufficient in airtightness when being used under a high-humidity environment or around water.

The present invention has been made in view of the above-described points, and it is an object of the present invention to provide a semiconductor light emitting device having a high joining property and high airtightness and having high environment resistance such as high reliability and low moisture permeability, etc.

A semiconductor light emitting device according to one aspect of the present invention includes a semiconductor light emitting element, a substrate mounted with the semiconductor light emitting element and including a substrate joining surface having an inner substrate joining surface to which an annular-shaped substrate metal layer is fixed, and an outer substrate joining surface being an outer adjacent region of the inner substrate joining surface, and a light transmitting cap having a window part transmitting light radiated from the semiconductor light emitting element and a flange having a flange joining surface to which an annular-shaped flange metal layer having a size corresponding to the substrate metal layer is fixed, the light transmitting cap having a space accommodating the semiconductor light emitting element and sealed and joined to the substrate. A sealing joining section between the substrate and the light transmitting cap has an inner joining part at which the substrate metal layer and the flange metal layer are joined by a metal joining material, and an outer joining part being an outer adjacent region of the inner joining part and being joined by an inorganic adhesive.

### BRIEF DESCRIPTION OF THE DRAWINGS

FIG. 1A is a plan view typically showing an upper surface of a semiconductor light emitting device 10 according to a first embodiment;

FIG. 1B is a view typically showing a side surface of the semiconductor light emitting device 10;

FIG. 1C is a plan view typically showing a back surface of the semiconductor light emitting device 10;

FIG. 1D is a view typically showing an internal structure of the semiconductor light emitting device 10;

FIG. 1E is a perspective view typically showing a ¼ part of a light transmitting cap 13 in the first embodiment;

FIG. 2 is a cross-sectional view typically showing a cross-section of the semiconductor light emitting device 10 taken along line A-A of FIG. 1A;

FIG. 3A is a cross-sectional view typically showing a state before a substrate 11 and the light transmitting cap 13 are joined;

FIG. 3B is a cross-sectional view typically showing a state after formation of an inner joining part between the substrate 11 and the light transmitting cap 13;

FIG. 3C is a cross-sectional view typically showing a state after formation of an outer joining part between the substrate 11 and the light transmitting cap 13;

FIG. 4A is a cross-sectional view typically showing a cross-section of a. semiconductor light emitting device 30 according to a second embodiment;

FIG. 4B is a partly enlarged cross-sectional view showing in an enlarged form, a joining part W between a substrate 11 and a light transmitting cap 13;

FIG. 5A is a cross-sectional view typically showing a cross-section of a semiconductor light emitting device 40 according to a third embodiment;

FIG. 5B is a partly enlarged cross-sectional view showing in an enlarged form, a joining part W between a substrate 11 and a light transmitting cap 13;

FIG. 5C is a cross-sectional view typically showing a method of forming an inorganic joining part 25;

FIG. 6A is a partly enlarged cross-sectional view showing in an enlarged form, a joining part W between a substrate 11 and a light transmitting cap 13 in a modified example of the third embodiment;

FIG. 6B is a partly enlarged cross-sectional view showing a joining part W between a substrate 11 and a light transmitting cap 13 in a modified example of the third embodiment;

FIG. 7A is a cross-sectional view typically showing a cross--section of a semiconductor light emitting device 50 according to a fourth embodiment;

FIG. 7B is a partly enlarged cross-sectional view showing in an enlarged form, a joining part W between a substrate 11 and a light transmitting cap 13 in the semiconductor light emitting device 50;

FIG. 8A is a plan view typically showing an upper surface of the semiconductor light emitting device 50 according to the fourth embodiment;

FIG. 8B is a view typically showing a side surface of the semiconductor light emitting device 50;

FIG. 8C is a view typically showing an internal structure of the semiconductor light emitting device 50;

FIG. 9A is a view showing a modified example of the fourth embodiment and is a plan view typically showing an upper surface of a semiconductor light emitting device 50 according to the modified example;

FIG. 9B is a view typically showing a side surface of the semiconductor light emitting device 50 according to the modified example; and

FIG. 9C is a view typically showing an internal structure of the semiconductor light emitting device 50 according to the modified example.

### DESCRIPTION OF THE PREFERRED EMBODIMENTS

Hereinafter, preferred embodiments of the present invention will be described, but these may be appropriately modified and combined. Further, in the following description and accompanying drawings, substantially the same or equivalent parts will be described with the same reference numerals attached thereto.

### First Embodiment

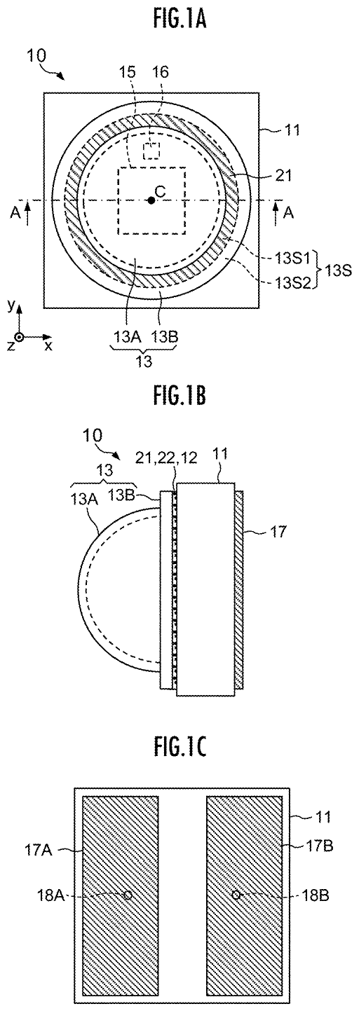

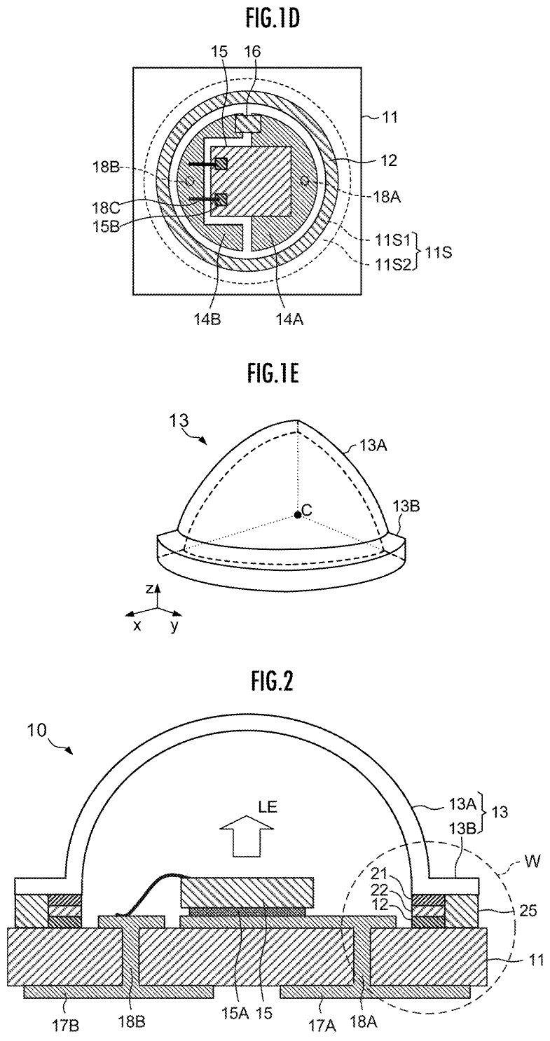

FIG. 1A is a plan view typically showing an upper surface of a semiconductor light emitting device 10 according to a first embodiment of the present invention. FIG. 1B is a view typically showing a side surface of the semiconductor light emitting device 10. FIG. 1C is a plan view typically showing a back surface of the semiconductor light emitting device 10. FIG. 1D is a view typically showing an internal structure of the semiconductor light emitting device 10. FIG. 2 is a cross-sectional view typically showing a cross-section of the semiconductor light emitting device 10 taken along line A-A of FIG. 1A.

As shown in FIGS. 1A and 1B, the semiconductor light emitting device 10 is comprised of a rectangular plate-shaped substrate 11 and a light transmitting cap 13 being a light transmissive window made of semispherical glass both being joined together. More specifically, an annular metal layer 12 (hereinafter also called a substrate metal layer 12) is formed on an upper surface of the substrate 11 and joined to the light transmitting cap 13.

Incidentally, a side surface of the substrate 11 is shown as parallel to an x direction and a y direction, and the upper surface of the substrate 11 is shown as parallel to an xy plane.

As shown in FIG. 1F and FIG. 2, the light transmitting cap 13 is comprised of a semispherical dome part 13A and a flange part 13B provided at the bottom of the dome part 13A being a light transmitting part. Incidentally, FIG. 1E is a perspective view typically showing a ¼ part of the light transmitting cap 13.

The flange part 13B has an annular plate shape. A flange metal layer 21 is fixed to the bottom of the flange part 13B to form a flange joining surface. The flange metal layer 21 is joined onto the substrate metal layer 12 by a metal joining layer 22 to thereby keep the substrate 11 and the light transmitting cap 13 airtight.

The substrate 11 is a ceramic substrate which does not make gas or the like permeate. For example, aluminum nitride (AlN) having thermal conductivity and excellent in airtightness is used. Incidentally, as a base material for the substrate 11, another ceramic excellent in airtightness such as alumina (Al₂O₃) can be used.

The light transmitting cap 13 is made of glass which transmits light emitted from a light emitting element 15 arranged in the semiconductor light emitting device 10. For example, quartz glass or borosilicate glass can be suitably used.

As filling gas in the semiconductor light emitting device 10, dry nitrogen gas, air or the like can be used, or the inside thereof may be evacuated.

As shown in FIG. 1D, a first wiring electrode (e.g., an anode electrode) 14A and a second wiring electrode (e.g., a cathode electrode) 14B each being a wiring electrode in the semiconductor light emitting device 10 are provided on the substrate 11 (hereinafter referred to as a wiring electrode 14 in the case where not distinguishing in particular). The semiconductor light emitting element 15 such as a light emitting diode (LED) or a semiconductor laser is joined onto the first wiring electrode 14A with a metal joining layer 15A. A bonding pad 15B of the light emitting element 15 is electrically connected to the second wiring electrode 14B through a bonding wire 18C.

The semiconductor light emitting element 15 is an aluminum gallium nitride (AlGaN)-based semiconductor light emitting element (LED) formed with a semiconductor structural layer including an n-type semiconductor layer, a light emitting layer, and a p-type semiconductor layer. Further, in the semiconductor light emitting element 15, the semiconductor structural layer is formed (joined) onto a conductive support substrate (silicon: Si) through a reflection layer.

The semiconductor light emitting element 15 has an anode electrode which is provided on the surface (also referred to as a back surface of the semiconductor light emitting element 15) opposite to the surface of the support substrate onto which the semiconductor structural layer is joined (not shown), and is electrically connected to the first wiring electrode 14A on the substrate 11. Further, the semiconductor light emitting element 15 has a cathode electrode (a cathode electrode pad 15B) which is provided on the surface (also referred to as a surface of the semiconductor light emitting element 15) opposite to the surface of the semiconductor structural layer onto which the support substrate is joined, and is electrically connected to the second wiring electrode 14B through a bonding wire 18C.

It is suitable that the semiconductor light emitting element 15 is an aluminum nitride-based light emitting element which emits an ultraviolet light having a wavelength of 250 nm to 415 nm. It is suitable that the semiconductor light emitting element 15 is an aluminum nitride-based light emitting element which emits an ultraviolet light having a wavelength of 250 nm to 270 nm particularly for sterilization applications. Specifically, a light emitting element having an emitted light center wavelength of 265 nm, 275 nm, 355 nm, 365 nm, 385 nm, 405 nm or 415 nm was used.

The Al composition of a semiconductor crystal which constitutes a light emitting element (UV-LED element) emitting aluminum nitride-based ultraviolet light is high and easy to be oxidized and deteriorated by water (H₂O) or excessive oxygen (O₂).

Further, a protective element 16 being a Zener diode (ZD) connected to the first wiring electrode 14A and the second wiring electrode 14B is provided on the substrate 11 and prevents electrostatic destruction of the light emitting element 15.

As shown in FIG. 1C, a first mounting electrode 17A and a second mounting electrode 17B (hereinafter referred to as a mounting electrode 17 particularly where not distinguishing) respectively connected to the first wiring electrode 14A and the second wiring electrode 14B are provided on the back surface of the substrate 11. Specifically, the first wiring electrode 14A and the second wiring electrode 14B are each respectively connected to the first mounting electrode 17A and the second mounting electrode 17B through metal vias 18A and 18B each made of, for example, copper (Cu).

Referring to FIG. 2, the semiconductor light emitting device 10 is mounted on a wiring circuit substrate (not shown). With the application of a voltage to the first mounting electrode 17A and the second mounting electrode 17B, the light emitting element 15 performs light emission and emits light LE radiated from the surface (light extraction surface) of the light emitting element 15 to the outside through the light transmitting cap 13.

The joining part between the substrate 11 and the flange part 13B of the light transmitting cap 13 will next be described.

### (Light Transmitting Cap 13 and Flange Part 13B)

Further, as shown in FIGS. 1A and 1B, the light transmitting cap 13 being a light transmissive cover member is comprised of a dome part 13A being a semispherical window part and a flange part 13B provided at the bottom of the dome part 13A. The flange part 13B has an annular plate shape. More specifically, the bottom surface of the flange part 13B has an annular shape (whose center: C) concentric to the center of the dome part 13A. That is, the outer edge (outer periphery) of the flange part 13B is concentric to the inner edge (inner periphery) of the flange part 13B.

### (Flange Metal Layer 21)

Further, the metal layer 21 is fixed to the bottom surface of the flange part 13B. More specifically, as shown in FIG. 1A and FIG. 2, the flange metal layer 21 being an annular-shaped metal layer is fixed to an annular-shaped bottom surface (hereinafter also referred to as a flange joining surface) 13S of the flange part 13B.

The flange metal layer 21 is fixed to an inner annular-shaped region (an inner flange surface) 13S1 of the flange joining surface 13S of the flange part 13B. The flange joining surface 13S further has an annular-shaped outer flange surface 13S2 being an outer adjacent region of the inner flange surface 13S1.

### (Substrate Metal Layer 12)

As shown in FIG. 1D, the substrate metal layer 12 being a metal annular body having an annular shape is fixed onto the substrate 11. More specifically, as shown in FIG. 1D and FIG. 2, the substrate metal layer 12 being an annular-shaped metal layer is fixed to an annular-shaped substrate joining surface 11S of the upper surface of the substrate 11.

The substrate metal layer 12 is fixed to an inner annular-shaped region (an inner substrate joining surface) 11S1 of the substrate joining surface 11S. The substrate joining surface 11S further has an outer substrate joining surface 11S2 being an outer adjacent region of the inner substrate joining surface 11S1.

The substrate metal layer 12 and the flange metal layer 21 have shapes (annular shapes) and sizes corresponding to each other respectively. That is, they respectively have the shapes and sizes matched when the substrate metal layer 12 and the flange metal layer 21 are joined.

Further, the substrate metal layer 12 is formed to be electrically insulated from the first wiring electrode 14A, the second wiring electrode 14B, the light emitting element 15, and the protective element 16 and surround these.

As shown in FIG. 2, the flange part 13B of the light transmitting cap 13 and the substrate 11 are joined by the metal joining layer 22 and the inorganic joining part 25.

### (Materials for Substrate Metal Layer 12, Flange Metal Layer 21, and Metal Joining Layer 22)

The substrate metal layer 12 has a structure (W/Ni/Au) having tungsten, nickel, and gold laminated on the substrate 11 in order or a structure (Ni/Cr/Au/Ni/Au) having nickel chromium, gold, nickel, and gold laminated thereon in order.

The flange metal layer 21 at the bottom surface of the flange part 13B has a structure (Cr/Ni/Au) having chromium, nickel, and gold laminated in order on the base material (glass) of the flange part 13B or a structure (Ti/Pd/Cu/Ni/Au) having titanium, palladium, copper, nickel, and god laminated thereon in order.

Incidentally, the structures of the above-described substrate metal layer 2 and flange metal layer 21 are only examples. For example, each of them may have a structure in which a barrier metal suppressing nterdiffusion and a metal high in adhesion are laminated on Au.

The joining material to be the metal joining layer 22 is, for example, an annular AuSn (gold tin) sheet which does not include flux. There was used one containing Sn of 22 wt % (melting temperature: about 300° C.). An Au (10 to 30 nm) layer can be provided on both surfaces of the gold tin alloy sheet. This prevents the AuSn alloy from oxidizing and improves airtightness. Further, the Au layer is dissolved in the metal joining layer 22 at the time of melting and solidification (joining).

### (Inorganic Joining Part 25)

An adhesive having strong adhesion, high hardness, airtightness, heat resistance, a thermal expansion coefficient, water resistance, pressure resistance, chemical resistance, etc., or the like can be used for the inorganic joining part 25. For example, there can be used a glass-based adhesive having quartz or the like as a base ingredient, or an adhesive of a ceramic-based inorganic material having alumina, zirconia, silica, graphite or the like as a base ingredient, etc.

More specifically, in an LED package in which the first wiring electrode 14A and the LED element are Au-Sn eutectic-joined at about 300° C., a reactive adhesive having a curing property at a temperature (e.g., 80° C. to 260° C.) lower than the eutectic joining temperature can be used. This type of inorganic adhesive mainly includes a polysilica-based adhesive of silicate system, aluminum oxide-silicate system, zirconium-silicate system, aluminum oxide-zirconium-silicate system, or the like.

Further, there is a metal aikoxide-based adhesive using ceramic such as alumina and various metal alkoxides (Si, Ti, ZrAl) as binders. These inorganic adhesives have high hardness and excellent heat resistance and adhesive strength. They have high airtightness such as low moisture permeability and are suitable.

For example, as an inorganic adhesive of aluminum oxide-zirconium-silicate system, one-pack adhesive composed of zirconium compound (60-70 wt %), silicate (5-1.5 wt %), aluminum oxide (1-3 wt %), and water (20-30 wt %) can be used.

### [Manufacturing Method of Light Emitting Device 10]

Hereinafter, a method of manufacturing the light emitting device 10 will be described in detail and specifically.

### (Element Joining Process)

First, AuSn volatile soldering paste solder is applied onto the first wiring electrode 14A of the substrate 11. As for this solder, AuSn composition solder of Au—Sn (22 wt %) having a melting temperature of about 300° C. was used.

Next, the light emitting element 15 is placed on the volatile solder paste, and the substrate is heated to 320° C. to melt and solidify AuSn, thereby joining the light emitting element 15 on the first wiring electrode 14A. Incidentally, when the protective element 16 is mounted, the above processing is performed simultaneously with it. At this time, flux contained in the volatile solder paste is almost volatilized.

Next, the bonding wire 18C (Au wire) electrically connects between the bonding pad 15B as the upper electrode of the light emitting element 15 and the second wiring electrode 14B.

### (Flux Additional Volatilization Process)

The substrate 11 to which the light emitting element 15 is joined as described above, is set to a heater and heated for 20 seconds at an annealing temperature of 300° C. under a nitrogen atmosphere to volatilize the residue (flux) of the volatile solder paste.

The lower limit of the additional volatilization temperature is preferably 300° C. or higher (i.e., a melting temperature or higher of the metal joining layer 22) at which the residue (flux) is volatilized. Further, the upper limit of the additional volatilization temperature is preferably below the temperature at which the metal joining layer 22 does not remelt, for example, 330° C. or less.

### (Excimer Light Cleaning Process)

The substrate 11 after the additional volatilization is set to an excimer light irradiation device and irradiated with an excimer light of 200 mJ/cm² or more. Consequently, the residue (flux) adsorbed on the surfaces of the substrate 11 and the light emitting element 15 was decomposed and removed.

(Cap Joining Process 1: inner Joining Part Formation)

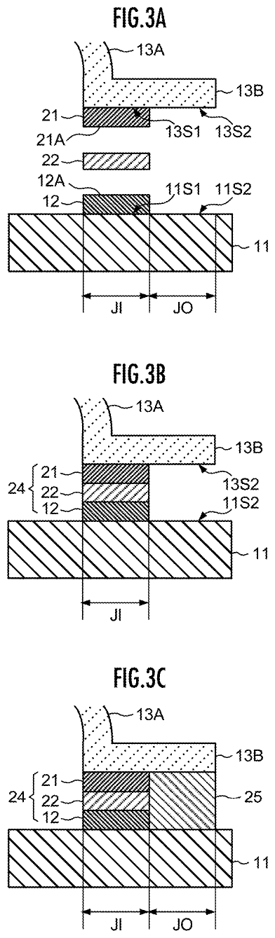

FIGS. 3A through 3C are partly enlarged cross-sectional views for describing a first joining process (a joining process 1) of a W part (a joining pail) in FIG. 2.

The substrate 11 after the excimer light cleaning process and the light transmitting cap 13 are set to a cap joining device. Next, the atmospheres of the substrate 11 and the light transmitting cap 13 are brought into a vacuum condition, and. they are heat-treated (annealed) for 5 minutes at a temperature 275° C.

Subsequently, the atmospheres of the substrate 11 and the light transmitting cap 13 are filled with dry nitrogen (N₂) gas being sealing gas at 1 atm (101.3 kPa). Next, an annular AuSn sheet (a joining material for the metal joining layer 22) is placed on the substrate metal layer 12 of the substrate 11. Further, the flange part 13B of the light transmitting cap 13 is placed from thereabove (refer to FIG. 3A).

The light transmitting cap 13 is heated to 320° C. while being pressed against the annular AuSn sheet. By its heating, the AuSn sheet is melted from a portion thereof adhered to the substrate metal layer 12 to the inside and outside and solidified while slightly melting gold of the metal layer 12 and the flange metal layer 21 or solidified by cooling. As shown in FIG. 3B, an inner joining part JI is formed which is comprised of a metal joining structure 24 in which the substrate metal layer 12 and the flange metal layer 21 are joined by the metal joining layer 22.

### (Cap Joining Process 2: Outer Joining Part Formation)

A liquid inorganic adhesive is filed in a region outside the inner joining part i.e., between the outer substrate joining surface 11S2 of the substrate joining surface 11S and the outer flange surface 1352 of the flange joining surface 135. This is heat-treated for 5 to 15 minutes at a temperature 100° C. to form an inorganic joining part 25. Consequently, as shown in FIG. 3C, an outer joining part JO is formed, and sealing junction between the substrate 11 and the light transmitting cap 13 is completed.

### (Double Airtight Structure)

As described above, the semiconductor light emitting device 10 according to the present embodiment has a double airtight structure comprised of the inner joining part Ji and the outer joining part JO.

The inner joining part JI has a sealing structure composed of a metal r Material (including alloy), which is comprised of the substrate metal layer 12, the metal joining layer 22, and the flange metal layer 21. The metal sealing structure has the function of preventing primary airtight sealing and intruding of volatile components generated upon the formation of the outer joining part into the cap.

The outer joining part JO has a sealing structure composed of an inorganic adhesive made of a glass-based or ceramic-based inorganic material. The inorganic adhesive sealing structure has the function of preventing secondary airtight sealing and corrosion of the inner joining part by atmospheric gas.

That is, the double airtight structure according to the present embodiment has the primary airtight sealing structure made of the metal material having expansibility and the secondary airtight sealing structure made of the inorganic material high in hardness. The semiconductor light emitting device can be provided which is strong against vibrations, impacts, etc. and has airtight joining high in environment resistance such as moisture resistance, corrosion resistance or the like.

### Second Embodiment

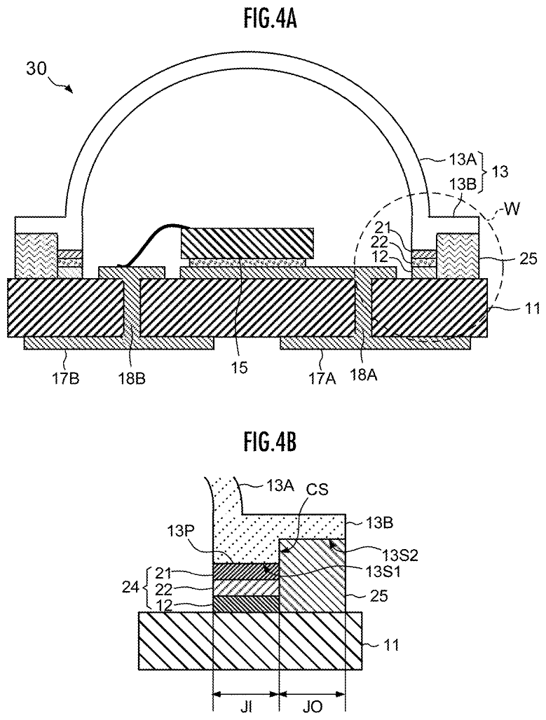

FIG. 4A is a view similar to FIG. 2 and is a cross-sectional view typically showing a cross-section of a semiconductor light emitting device 30 according to a second embodiment of the present invention. 4B is a partly enlarged cross-sectional view showing in an enlarge form, a joining part W between a substrate 11 and a light transmitting cap 13.

In the second embodiment, a flange part 13B of the light transmitting cap 13 has a flange protruding portion 13P which protrudes at an inner flange surface 13S1.

More specifically, the bottom surface (inner flange surface 13S1) of the flange protruding portion 13P has an annular shape, and a flange metal layer 21 is fixed to the inner flange surface 13S1.

Further, a substrate metal layer 12 is fixed to an inner annular-shaped region (an inner substrate joining surface) 11S1 of a substrate joining surface 11S. The substrate metal layer 12 and the flange metal layer 21 have shapes (annular shapes) and sizes corresponding to each other respectively.

The substrate metal layer 12 and the flange metal layer 21 are joined by a metal joining layer 22 to form an inner joining part JI comprised of a metal joining structure 24 being a metal sealing structure.

Further, an outer substrate joining surface 11S2 of the substrate joining surface 11S and an outer flange surface 13S2 of a flange joining surface 13S are joined by an inorganic joining part 25, so that an outer joining part JO comprised of a sealing structure made of an inorganic adhesive is formed.

In the semiconductor light emitting device 30 according to the present embodiment, since the flange protruding portion 13P is provided therein and a joining surface CS is formed even between the side surface of the flange protruding portion 13P and the inorganic joining part 25, the joining strength against lateral stress is improved.

Further, since the outer joining part JO is made of the inorganic adhesive high in hardness, the load to the inner joining part JI can be reduced, thereby making it possible to prevent degradation in airtightness of the inner joining part JI.

As described above, the semiconductor light emitting device 30 according to the present embodiment has a double airtight structure comprised of the inner joining part JI and the outer joining part JO. Thus, as with the above embodiment, there can be provided a semiconductor light emitting device which is strong against vibrations, impacts, etc. and has airtight joining high in moisture resistance and corrosion resistance.

### Third Embodiment

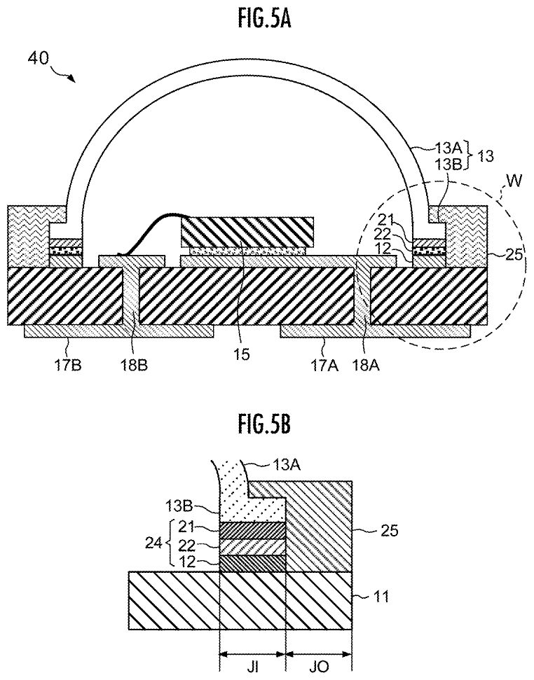

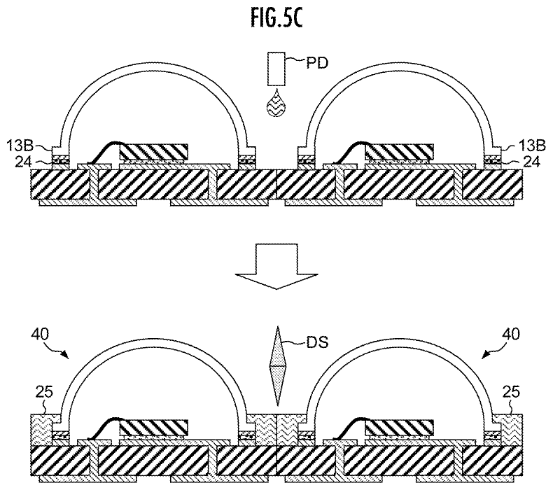

FIG. 5A is a view similar to FIG. 2 and is a cross-sectional view typically showing a cross-section of a semiconductor light emitting device 40 according to a third embodiment of the present invention. FIG. 5B is a partly enlarged cross-sectional view showing in an enlarge form, a joining part W between a substrate 11 and a light transmitting cap 13.

In the third embodiment, a flange surface 13S being the bottom surface of a flange part 13B has an annular shape, and a flange metal layer 21 is fixed thereto. Further, a substrate metal layer 12 is fixed to an inner annular-shaped region (an inner substrate joining surface) 11S1 of a substrate joining surface 11S. The substrate metal layer 12 and the flange metal layer 21 have shapes (annular shapes) and sizes corresponding to each other respectively.

The substrate metal layer 12 and the flange metal layer 21 are joined by a metal joining layer 22 to form an inner joining part JI comprised of a metal sealing structure.

Further, an outer joining part JO comprised of an inorganic joining part 25 is formed so as to cover the inner joining part JI, i.e., so as to reach up to the upper surface of the flange part 13B and cover a metal joining structure 24 and the flange part 13B.

FIG. 5C is a cross-sectional view typically showing a method of forming the inorganic joining part 25. As shown in the upper-stage figure in FIG. 5C, a slurry of inorganic adhesive is potted in an outer joining region between adjacent semiconductor light emitting devices by a potting device PD until the end of the flange part 13B is buried. Following the above, cure (curing of the inorganic adhesive) is performed to solidify the inorganic adhesive, thereby forming the inorganic joining part 25.

Subsequently, the inorganic joining part 25 between the adjacent semiconductor light emitting devices is divided into each individual semiconductor light emitting device 40 by a dicer DS or laser dicing (the lower stage in FIG. 5C), whereby the semiconductor light emitting device 40 is manufactured.

With such a structure, the joining strength between the substrate 11 and the light transmitting cap 13 is further improved. Incidentally, as shown in FIGS. 5A and 5B, the inorganic joining part 25 is preferably formed so as to cover the entire upper surface of the flange part 13B.

### (Modified Examples of Third Embodiment)

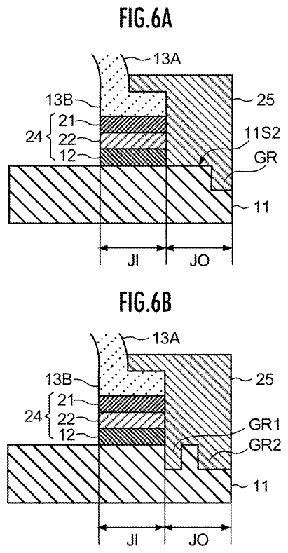

FIGS. 6A and 6B are views similar to FIG. 5B and partly enlarged cross-sectional views showing in an enlarge form, a joining part W between a substrate 11 and a light transmitting cap 13 in each modified example of the third embodiment.

Referring to FIG. 6A, a groove GR is formed in an outer substrate joining surface 11S2. Also, referring to FIG. 6B, an inner groove GR1 and an outer groove GR2 (hereinafter collectively called a groove GR where there is no particular distinction) are formed in the outer substrate joining surface 11S2.

That is, at least one groove GR is formed in the outer substrate joining surface 11S2. The groove GR is formed as an annular groove (a groove of an outer ring) surrounding an inner joining part JI. Incidentally, the groove GR may be formed to be at least a part of the outer ring instead of a closed ring shape.

Then, an inorganic joining part 25 is formed so as to fill the at least one groove GR.

With such a structure, it is possible to further improve the joining strength of an outer joining part JO. It is also possible to prevent the cap from coming off.

In the above, the double airtight structure comprised of the inner joining part JI and the outer joining part JO has been described, but it is also possible to add ingenuity for improving further airtightness. For example, it is also possible to roughen the contact surface between the light transmitting cap and the substrate 11 with which an inorganic adhesive comes into contact, to improve bindability of the inorganic joining part 25.

As described above, the semiconductor light emitting device 40 according to the present embodiment also has the double airtight structure comprised of the inner joining part JI and the outer joining part JO. Thus, as with the above-described embodiment, there can be provided a semiconductor light emitting device which is strong against vibrations, impacts, etc. and has airtight joining high in moisture resistance and corrosion resistance.

### Fourth Embodiment

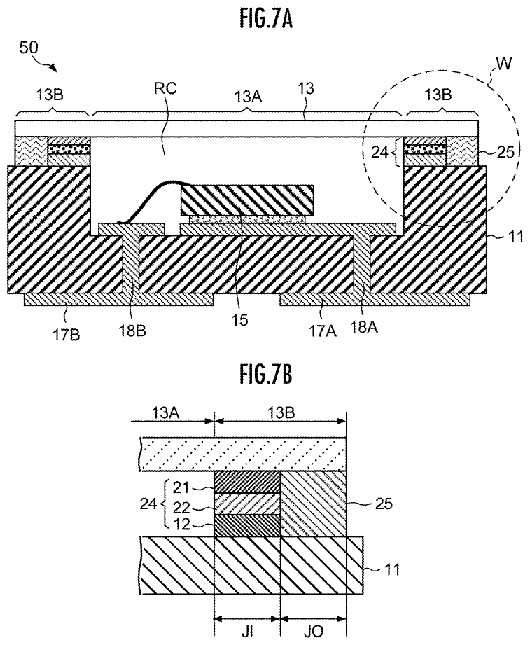

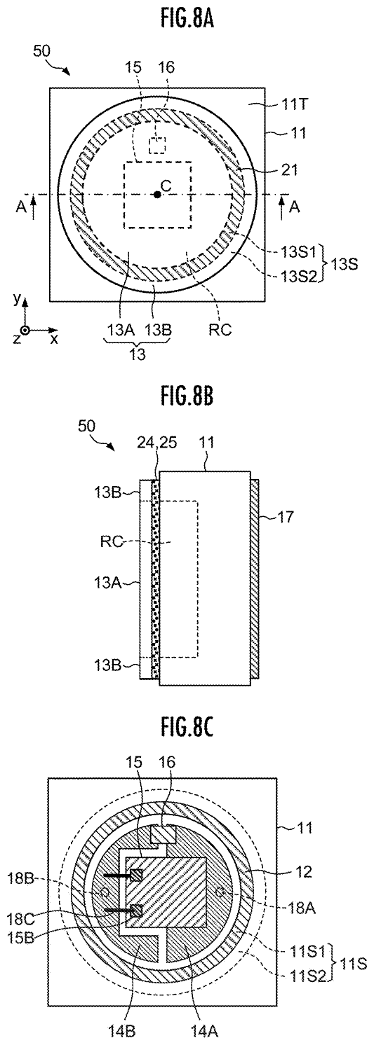

FIG. 7A is a cross-sectional view typically showing a cross-section (a cross-section taken along line A-A of FIG. 8A) of a semiconductor light emitting device 50 according to a fourth embodiment of the present invention. FIG. 7B is a partly enlarged cross-sectional view showing in an enlarge form, a joining part W between a substrate 11 and a light transmitting cap 13.

Further, FIG. 8A is a plan view typically showing an upper surface of the semiconductor light emitting device 50 according to the fourth embodiment, FIG. 8B is a view typically showing a side surface of the semiconductor light emitting device 50. FIG. 8C is a view typically showing an internal structure of the semiconductor light emitting device 50.

As shown in FIGS. 7A and 8A, the light transmitting cap 13 of the fourth embodiment is a disc-shaped flat plate. An annular-shaped outer edge part of the light transmitting cap 13 is a flange part 13B, and the inside thereof is a window part 13A being a light transmitting part. An annular-shaped flange metal layer 21 is fixed to the bottom surface (i.e., an annular-shaped outer peripheral part of the bottom surface of the light transmitting cap 13) of the flange part 13B, so that a metal joining surface is formed.

As shown in FIGS. 7A, 8A and 8B, the substrate 11 has a recess part RC being space accommodating a light emitting element 15 thereinside. More specifically, the substrate 11 is configured as a housing (a frame structure) having a cylindrical recess part RC defined by an inner edge of the substrate 11. The light transmitting cap 13 is placed and joined onto a top surface 11T of the substrate 11.

As shown in FIG. 8C, a substrate metal layer 12 is fixed to an inner annular-shaped region (an inner substrate joining surface) 11S1 of a substrate joining surface 11S. The substrate metal layer 12 has a shape (an annular shape) and a size corresponding to a flange metal layer 21.

As shown in FIG. 713, the substrate metal layer 12 and the flange metal layer 21 are joined by a metal joining layer 22 to form an inner joining part JI comprised of a metal joining structure 24 being a metal sealing structure.

Further, an outer substrate joining surface 11S2 of the substrate joining surface 11S and an outer flange surface 13S2 of a flange joining surface 13S are joined by an inorganic joining part 25, so that an outer joining part JO comprised of a sealing structure made of an inorganic adhesive is formed,

### (Modified Example of Fourth Embodiment)

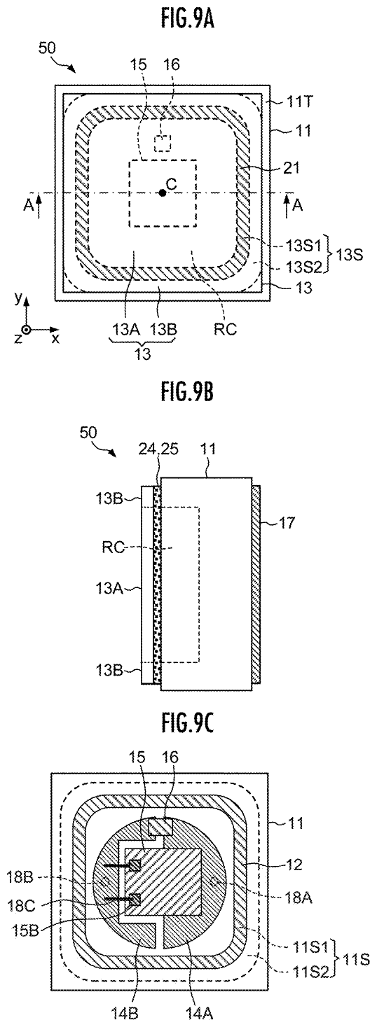

FIGS. 9A, 9B and 9C are views showing a modified example of the fourth embodiment, in which FIG. 9A is a plan view typically showing an upper surface of a semiconductor light emitting device 50, FIG. 9B is a view typically showing a side surface thereof, and FIG. 9C is a view typically showing an internal structure thereof, respectively. Incidentally, a cross-section of the semiconductor light emitting device 50 taken along line A-A of FIG. 9A, and a partly enlarged cross-section of a joining part W are respectively similar to FIGS. 7A and 7B.

Incidentally, as shown in FIG. 9A in the present modified example, a light transmitting cap 13 is a rectangular flat plate, a rectangular annular-shaped outer edge part of the light transmitting cap 13 is a flange part 13B, and the inside thereof is a window part 13A being a light transmitting part. A rectangular annular-shaped flange metal layer 21 is fixed to a bottom surface of the flange part 13B to form a metal joining surface. Incidentally, the flange metal layer 21 has a chamfered shape whose corner is an R surface.

As shown in FIGS. 9A to 9C, a recess part RC accommodating a light emitting element 15 has a prismatic shape. Incidentally, the recess part RC has a prismatic shape whose corner is R-face processed (chamfered).

As shown in FIG. 9C, a substrate metal layer 12 is fixed to an inner rectangular annular-shaped region (an inner substrate joining surface) 11S1 of a substrate joining surface 115. The substrate metal layer 12 has a shape (a rectangular annular shape) and a size corresponding to the flange metal layer 21.

As shown in FIG. 7B, the substrate metal layer 12 and the flange metal layer 21 are joined by a metal joining layer 22 to form an inner joining part JI comprised of a metal joining structure 24 being a metal sealing structure.

Further, an outer substrate joining surface 11S2 of the substrate joining surface 11S and an outer flange surface 13S2 of a flange joining surface 135 are joined by an inorganic joining part 25, so that an outer joining part JO comprised of a sealing structure made of an inorganic adhesive is formed.

In the semiconductor light emitting device 50 according to the present embodiment, the light transmitting cap 13 is comprised of a disk-shaped flat plate. The light transmitting cap 13 is easy in processing and also high in uniformity of joining with a substrate, and can also be reduced in cost. Further, it is possible to obtain a sufficient airtight joining property as long as the corners of the inner joining part JI and the outer joining part JO are rounded (R-face chamfered) even in the rectangular light transmitting cap 13B.

Further, the semiconductor light emitting device 50 according to the present embodiment has the double airtight structure comprised of the inner joining part JI and the outer joining part JO. Thus, as with the above-described embodiment, there can be provided a semiconductor light emitting device which is strong against vibrations, impacts, etc. and has airtight joining high in moisture resistance and corrosion resistance.

Incidentally, in the present specification, the term rectangular, rectangular annular shape and prismatic shape, etc. include shapes whose corners are subjected to R-face, C-face or other chamfering,

Incidentally, the above-described embodiment has described the case where the substrate metal layer 12 and the flange metal layer 21, etc. have the annular shapes, but are not limited thereto. For example, these metal layers may have a polygonal shape or a polygonal shape whose corner is chamfered.

Incidentally, the semiconductor material and the metal material, the numerical values, etc. described above are exemplary and not to be construed in a limited manner unless otherwise specified,

Further, in the present specification, the term “annular” includes an elliptical ring, an oval ring, an oval-shaped ring, etc. The same applies to the circle, the sphere, the cylinder, etc. too. In addition, the term “rectangular” includes a square, a rectangle, and shapes in which the corners of these are chamfered. The same applies to the rectangular ring, the prism and the like too.

As described in detail above, according to the present invention, there can be provided a highly reliable and long-life semiconductor light emitting device having a high joining property and high airtightness and having high environment resistance even under a bad environment such as high humidity.

### DESCRIPTION OF REFERENCE NUMERALS

10, 30 semiconductor light emitting device

11 substrate

11S substrate joining surface

13S flange joining surface

12 substrate metal layer

13 light transmitting cap

13A window part

13B flange part

13P flange protruding portion

21 flange metal layer

22 metal joining layer

24 metal joining structure

25 inorganic joining part

GR groove

JI inner joining part

JO outer joining part

RC recess part

What is claimed is:

1. A semiconductor light emitting device comprising:
a semiconductor light emitting element;
a substrate mounted with the semiconductor light emitting element and having a substrate joining surface having an inner substrate joining surface to which an annular- shaped substrate metal layer is fixed, and an outer substrate joining surface being an outer adjacent region of the inner substrate joining surface; and
a light transmitting cap having a window part transmitting light radiated from the semiconductor light emitting element and a flange having a flange joining surface to which an annular-shaped flange metal layer having a size corresponding to the substrate metal layer is fixed, the light transmitting cap having a space accommodating the semiconductor light emitting element and sealed and joined to the substrate,
wherein a sealing joining section between the substrate and the light transmitting cap has an inner joining part at which the substrate metal layer and the flange metal layer are joined by a metal joining material, and an outer joining part being an outer adjacent region of the inner joining part and being joined by an inorganic adhesive.

2. The semiconductor light emitting device according to claim 1, wherein the substrate metal layer and the flange metal layer have an annular shape.

3. The semiconductor light emitting device according to claim 1, wherein the inorganic adhesive is a glass-based or ceramic-based inorganic adhesive.

4. The semiconductor light emitting device according to claim 1, wherein the window part of the light transmitting cap has a semispherical shape.

5. The semiconductor light emitting device according to claim 1, wherein the light transmitting cap has a flat plate shape.

6. The semiconductor light emitting device according to claim 1, wherein the flange has a flange protruding portion which protrudes from a bottom surface of the flange in an inner region of the bottom surface, and the flange metal layer is fixed to a bottom surface of the flange protruding portion.

7. The semiconductor light emitting device according to claim 1, wherein the outer joining part is formed to reach up to an upper surface of the flange and cover the inner joining part and the flange.

8. The semiconductor light emitting device according to claim 1, wherein the outer substrate joining surface has at least one groove of an outer ring surrounding the inner substrate joining surface or at least a partial groove of the outer ring, and wherein the inorganic adhesive is formed to fill the groove.

9. The semiconductor light emitting device according to claim 1, wherein the light transmitting cap is made of quartz glass or borosilicate glass.

10. The semiconductor light emitting device according to claim 1, wherein the semiconductor light emitting element is an aluminum gallium nitride (AlGaN)-based semiconductor light emitting element.

11. The semiconductor light emitting device according to claim 10, wherein the semiconductor light emitting element emits an ultraviolet light having a wavelength of 250 nm to 415 nm.
